(19) United States
(12) Patent Application Publication
(10) Pub. No.: US 2026/0223338 A1
(43) Pub. Date: Jul. 30, 2026

(54) Liquid Cooling Power Conversion System

(71) Applicant: AA Power Inc., Boston, MA (US)

(72) Inventor: Qun Lu, Lexington, MA (US)

(21) Appl. No.: 19/458,786

(22) Filed: Jan. 24, 2026

Related U.S. Application Data
(60) Provisional application No. 63/749,445, filed on Jan. 24, 2025.

(51) Int. Cl. H05K 7/20

(52) U.S. Cl. CPC H05K 7/20927; H05K 7/20763

(57) ABSTRACT

A plurality of power supply units on a power shelf and connected between a power source and an output voltage bus, and a plurality of housings, wherein at least one of the plurality of housings is configured to accommodate a power supply unit, and wherein the at least one of the plurality of housings comprises a first sidewall portion, a second sidewall portion, a bottom case portion and a top case portion, and wherein at least one of the first sidewall portion and the second sidewall portion comprises a channel through which coolant flows to cool heat generation components of the power supply unit.

### PRIORITY

This application claims the benefit of U.S. Provisional Application No. 63/749,445, filed on January 24, 2025, entitled “Liquid Cooling Power Conversion System,” which application is hereby incorporated herein by reference.

### TECHNICAL FIELD

The present invention relates to a power conversion system, and in particular to a liquid cooling power conversion system for high power applications.

### BACKGROUND

As technologies further advance, a modern data center is equipped with numerous high-performance processors such as graphics processing units (GPUs). The processors are designed to handle intensive computing workloads such as artificial intelligence (AI) training, machine learning, and complex simulations. These GPUs, often organized into high-density racks, deliver exceptional parallel processing power, enabling the rapid analysis and processing of vast amounts of data.

As the demand for AI computing power continues to grow, and chip power consumption increases, liquid cooling technology has emerged as a vital solution for addressing the high-power requirements of data centers. In conventional power supply designs, the primary transmission of large currents is handled through printed circuit boards (PCBs). However, as the power demands of AI computing systems escalate, the higher current flowing through components such as PCBs and distribution connectors introduces a series of challenges. First, in existing power supply designs, power circuits and signal control circuits are routed on PCBs, with large currents partially interconnected through metal bus bars. The PCBs are thermally bonded to the case using thermal adhesive, allowing heat generated by components on the PCB and the bus bar to be transferred to the case or cooling system via the adhesive. As power levels increase, the large currents flowing through the PCBs generate excessive heat, leading to significant thermal management challenges. For example, inadequate cooling capacity results in elevated temperatures, adversely affecting the performance and lifespan of the circuit board and its components. Furthermore, high temperatures can cause solder joint degradation, component failure, or reduced reliability over time. Second, to accommodate higher power levels, metal bus bars used for current interconnections must be larger and heavier, which negatively impacts the power supply’s overall power density. Increased bus bar size and weight not only consume valuable space but also reduce design flexibility, complicating the integration of other critical components in compact systems.

Traditional power connectors in AI server systems primarily rely on air convection for cooling. As power demands rise, these connectors struggle with insufficient cooling efficiency under high loads or prolonged operation, resulting in overheating. Overheating in air-cooled connectors can cause insulation materials to melt or burn, leading to potential issues such as electrical arcing, sparks, or even fire hazards. Additionally, the limited current-carrying capacity of these air-cooled connectors hinders their ability to meet the increasing power requirements of AI computing systems, posing a critical bottleneck in power supply design. The limitations in traditional power supply designs highlight the need for having an efficient cooling system to mitigate this issue. The present disclosure addresses this need.

### SUMMARY

These and other problems are generally solved or circumvented, and technical advantages are generally achieved, by preferred embodiments of the present disclosure which provide a liquid cooling power conversion system for high power applications.

In accordance with an embodiment, a system comprises a plurality of power supply units on a power shelf and connected between a power source and an output voltage bus, and a plurality of housings, wherein at least one of the plurality of housings is configured to accommodate a power supply unit, and wherein the at least one of the plurality of housings comprises a first sidewall portion, a second sidewall portion, a bottom case portion and a top case portion, and wherein at least one of the first sidewall portion and the second sidewall portion comprises a channel through which coolant flows to cool heat generation components of the power supply unit.

In accordance with another embodiment, a system comprises a liquid cooling board comprising a channel through which coolant flows to cool heat generation components of the system, a first printed circuit board and a second printed circuit board on opposite sides of the liquid cooling board, a plurality of first power modules coupled between the liquid cooling board and the first printed circuit board, wherein each first power module is connected to the liquid cooling board through a first soft thermally conductive layer, and a plurality of second power modules coupled between the liquid cooling board and the second printed circuit board, wherein each second power module is connected to the liquid cooling board through a second soft thermally conductive layer.

In accordance with another embodiment, a system comprises a power shelf configured to receive a plurality of power supply units and to provide an output voltage bus, a busbar clip configured to electrically couple at least one of the plurality of power supply units to the output voltage bus, wherein the busbar clip is configured to carry a high current, and a liquid cooling channel disposed in the power shelf, wherein the busbar clip is thermally coupled to the liquid cooling channel such that coolant flowing through the liquid cooling channel absorbs heat generated by the busbar clip during operation.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a printed circuit board mounted on a liquid cooling board in accordance with various embodiments of the present disclosure;

FIG. 2 illustrates a printed circuit board mounted on a sidewall of a housing of a power conversion system in accordance with various embodiments of the present disclosure ;

FIG. 3 illustrates a printed circuit board mounted on a bottom case portion of a housing of a power conversion system in accordance with various embodiments of the present disclosure;

FIG. 4 illustrates a perspective view of a housing of a power supply unit in accordance with various embodiments of the present disclosure;

FIG. 5 illustrates a cross-sectional view of a liquid cooling power conversion system in accordance with various embodiments of the present disclosure;

FIG. 6 illustrates a perspective view of a power shelf in accordance with various embodiments of the present disclosure;

FIG. 7 illustrates a first cooling implementation in a power shelf in accordance with various embodiments of the present disclosure;

FIG. 8 illustrates a first cooling implementation of the male and female connectors in accordance with various embodiments of the present disclosure;

FIG. 9 illustrates a second cooling implementation of the male and female connectors in accordance with various embodiments of the present disclosure;

FIG. 10 illustrates a third cooling implementation of the male and female connectors in accordance with various embodiments of the present disclosure;

FIG. 11 illustrates a second cooling implementation in the power shelf in accordance with various embodiments of the present disclosure; and

FIG. 12 illustrates a cross-sectional view of another liquid cooling power conversion system in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to preferred embodiments in a specific context, namely a power conversion system, and more particularly, a liquid cooling power conversion system for high power applications. The disclosure may also be applied, however, to a variety of power conversion systems. Hereinafter, various embodiments will be explained in detail with reference to the accompanying drawings.

The present disclosure discloses a novel design for a liquid cooling power conversion system. The liquid cooling power conversion system comprises at least one power supply unit. This power supply unit is in a housing. The liquid cooling power conversion system integrates a printed circuit board with a liquid cooling plate. One of the sidewall portions of the housing is implemented as the liquid cooling plate. The printed circuit board is also known as a metal circuit board. In some embodiments, the printed circuit board is a metal-core printed circuit board, while in other embodiments the printed circuit board may be implemented using other suitable structures. Furthermore, the liquid cooling power conversion system integrates another printed circuit board with a metal case. The metal case is a bottom case portion of the housing.

In this design, large currents only flow through the metal circuit board, which is seamlessly integrated with the metal case. The metal case functions as both the liquid cooling plate and a metal bus bar, enabling efficient electrical interconnection of components. This novel design addresses the challenges of excessive heat and large component volume during interconnection, leveraging the superior heat dissipation capability of the liquid cooling plate case. Additionally, a new power supply unit (PSU) structure is built around this case design.

The present disclosure further discloses comprehensive architectures for liquid-cooled power supplies and innovative liquid-cooled connector solutions. These solutions include male and female connectors specifically designed with effective liquid cooling capabilities, providing enhanced heat dissipation. This design eliminates the overheating issues seen in conventional connectors and significantly increases their current density.

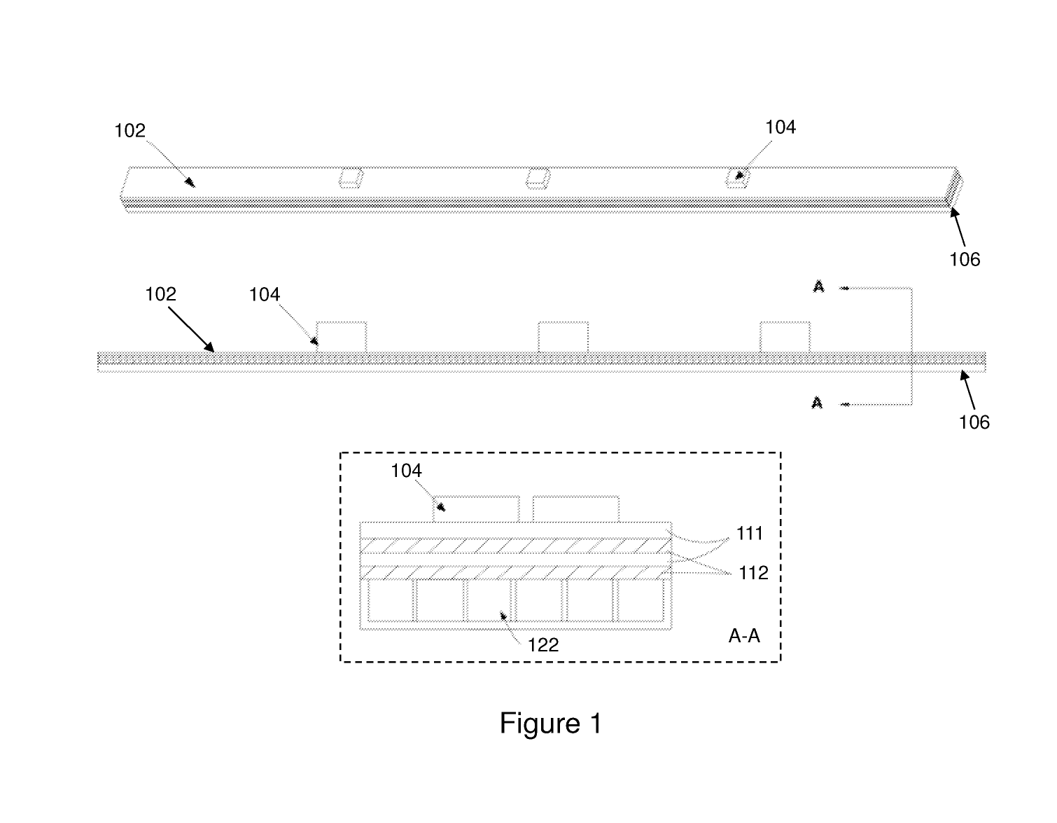

FIG. 1 illustrates a printed circuit board mounted on a liquid cooling board in accordance with various embodiments of the present disclosure. Throughout this disclosure, the liquid cooling board may also be referred to as a liquid cooling plate. The upper portion of FIG. 1 illustrates a perspective view of an apparatus including a plurality of electronic components 104, the printed circuit board 102, and the liquid cooling board 106. As shown in FIG. 1, the plurality of electronic components 104 is mounted on a first side of the printed circuit board 102. The printed circuit board 102 is over the liquid cooling board 106. In particular, a first side of the printed circuit board 102 is in direct contact with the liquid cooling board 106. In some embodiments, the first side is the front side of the printed circuit board 102. The second side is the backside of the printed circuit board 102.

The middle portion of FIG. 1 illustrates a cross-sectional view of the apparatus including the plurality of electronic components 104, the printed circuit board 102, and the liquid cooling board 106. The lower portion of FIG. 1 illustrates a cross-sectional view along lines A-A shown in FIG. 1.

As shown in FIG. 1, the printed circuit board 102 comprises a plurality of conductive layers 111 and a plurality of insulation layers 112, which are arranged in an alternating manner. The metal traces on the conductive layers 111 are electrically connected to the electronic components via connection columns or through-holes, allowing the power current and certain signals to flow through the printed circuit board.

As shown in FIG. 1, the multiple conductive layers 111 separated by insulating layers 112 ensure excellent thermal conductivity while preventing electrical leakage. Some electronic components 104 are heat generation components. As shown in FIG. 1, the heat generation components are mounted on a top conductive layer of the plurality of conductive layers 111. A bottom insulation layer of the plurality of insulation layers 112 is in direct contact with the liquid cooling plate 106.

In some embodiments, the liquid cooling board 106 is formed of any suitable thermally conductive materials such as copper, aluminum, any combination thereof and the like. As shown in FIG. 1, the liquid cooling board 106 comprises a plurality of liquid channels 122 through which coolant circulates, enabling the board to function as a liquid cooling plate. Throughout the description, the liquid cooling board may be alternatively referred to as a liquid cooling plate.

In some embodiments, the printed circuit board 102 and the liquid cooling plate 106 are part of a liquid cooling power system comprising a plurality of power supply units. The printed circuit board 102 is configured to accommodate various heat generation components of a power supply unit. The power supply unit is in a housing. The liquid cooling plate 106 is in contact with a sidewall portion of the housing. The sidewall portion of the housing comprising a liquid channel through which coolant circulates to lower the temperature of the sidewall. In some embodiments, the liquid cooling power system integrates the liquid cooling path of the sidewall with that of the liquid cooling plate 106 under the printed circuit board 102.

In operation, liquid cooling channels of the sidewall portion of the housing form a liquid path through which coolant circulates, enabling the sidewall portion of the housing to function as another liquid cooling plate. This design efficiently dissipates heat, significantly reducing the equipment's operating temperature.

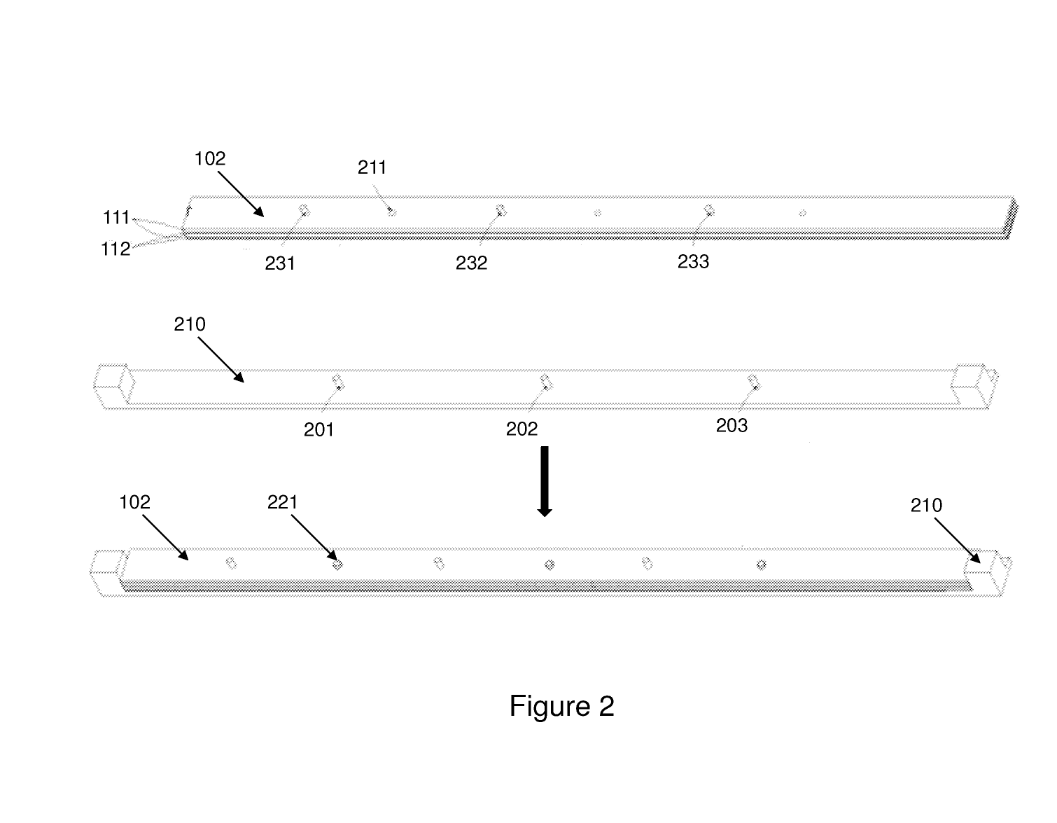

FIG. 2 illustrates a printed circuit board mounted on a sidewall of a housing of a power conversion system in accordance with various embodiments of the present disclosure. As shown in FIG. 2, a plurality of connecting studs 201, 202 and 203 is mounted on the first sidewall portion 210 of the housing. A plurality of electrical connection posts 231, 232 and 233 is formed over the printed circuit board 102. The electrical connection posts 231, 232 and 233 are configured to function as input/output terminals of the printed circuit board 102.

The printed circuit board 102 comprises a plurality of conductive layers 111 and a plurality of insulation layers 112 as shown in FIG. 2. The conductive layers 111 provide electrical connections for internal circuits of the printed circuit board 102. The electrical connection posts 231, 232 and 233 provide electrical connections between the printed circuit board 102 and external circuits.

A plurality of screw holes 211 is formed in the printed circuit board 102. Each of the plurality of connecting studs 201, 202 and 203 extends through a corresponding screw hole 211. The printed circuit board 102 is fastened to the first sidewall portion 210 through a plurality of screws 221. As shown in FIG. 2, the bottom insulation layer of the plurality of insulation layers is a thermally conductive but electrically insulating layer to prevent short circuits.

In some embodiments, the first sidewall portion 210 is configured as a system ground. At least one of the plurality of connecting studs 201, 202 and 203 is configured as a connecting channel between the printed circuit board 102 and the system ground.

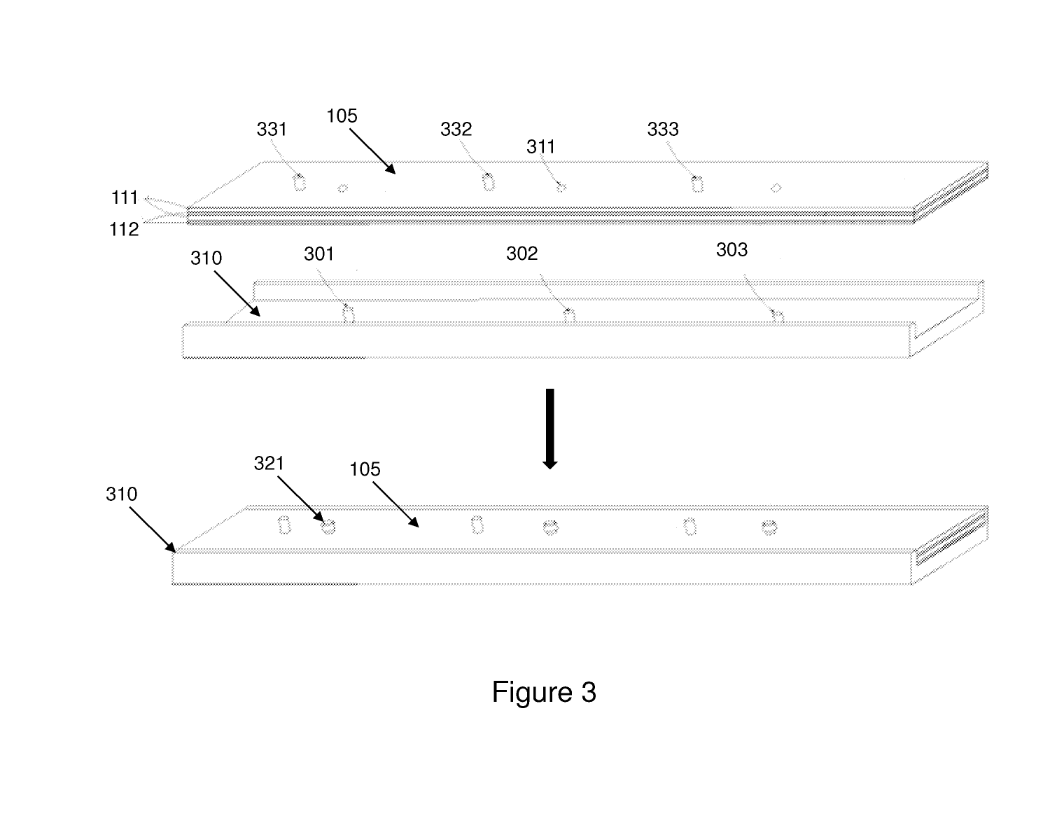

FIG. 3 illustrates a printed circuit board mounted on a bottom case portion of a housing of a power conversion system in accordance with various embodiments of the present disclosure. As shown in FIG. 3, a plurality of connecting studs 301, 302 and 303 is mounted on the bottom case portion 310 of the housing. A plurality of electrical connection posts 331, 332 and 333 is formed over the printed circuit board 105. The electrical connection posts 331, 332 and 333 are configured to function as input/output terminals of the printed circuit board 105.

The printed circuit board 105 comprises a plurality of conductive layers 111 and a plurality of insulation layers 112 as shown in FIG. 3. The conductive layers 111 provide electrical connections for internal circuits of the printed circuit board 105. The electrical connection posts 331, 332 and 333 provide electrical connections between the printed circuit board 105 and external circuits.

A plurality of screw holes 311 is formed in the printed circuit board 105. Each of the plurality of connecting studs 301, 302 and 303 extends through a corresponding screw hole 311. The printed circuit board 105 is fastened to the bottom case portion 310 through a plurality of screws 321. As shown in FIG. 3, the bottom insulation layer of the plurality of insulation layers is a thermally conductive but electrically insulating layer to prevent short circuits.

In some embodiments, the bottom case portion 310 is configured as a system ground. At least one of the plurality of connecting studs 301, 302 and 303 is configured as a connecting channel between the printed circuit board 105 and the system ground.

The connection between the printed circuit board 105 and the bottom case portion 310 shown in FIG. 3 is merely an example. Depending on different applications and design needs, there may be variations. For example, these two can be bonded together using a thermally conductive, electrically insulating ceramic adhesive or ceramic thermal interface material. It is initially soft and pliable, allowing easy application and conformation to irregular surfaces. Once heated, the material hardens, creating a strong and durable bond between the PCB and the heat sink.

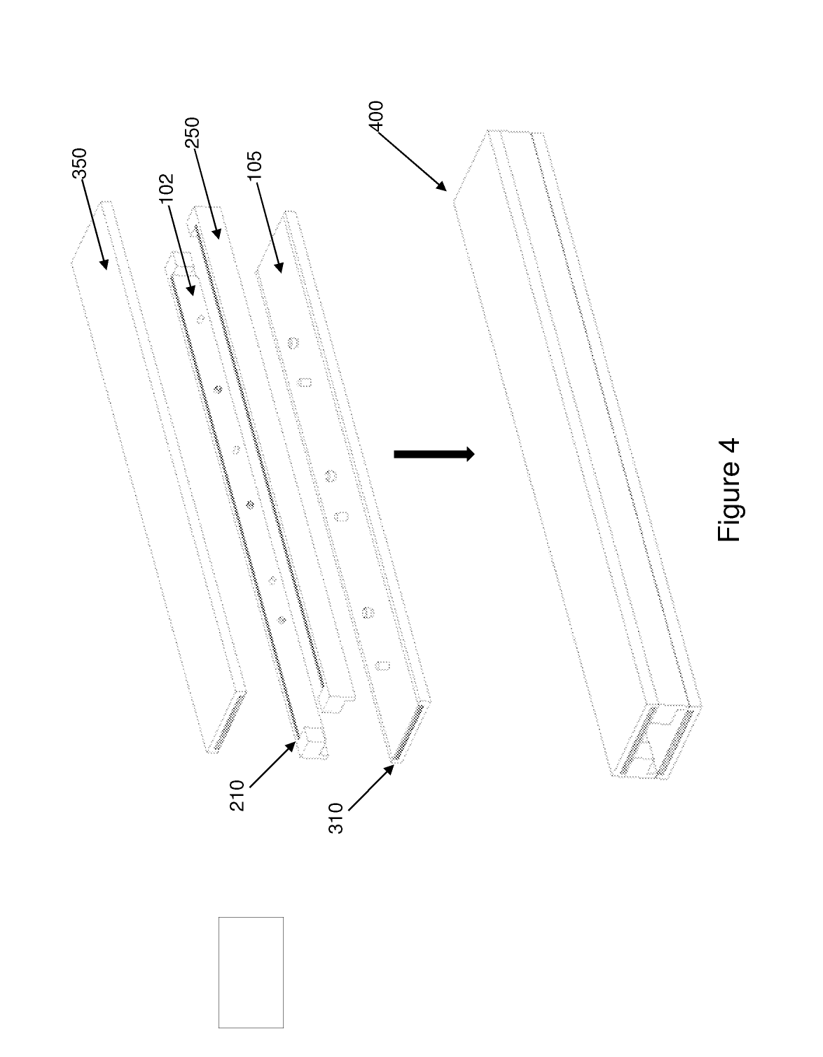

FIG. 4 illustrates a perspective view of a housing of a power supply unit in accordance with various embodiments of the present disclosure. As shown in FIG. 4, the housing 400 is assembled from a plurality of structural portions, including a first sidewall portion 210, a second sidewall portion 250, a bottom case portion 310, and a top case portion 350. These portions are mechanically coupled together to form an enclosed housing configured to accommodate the power supply unit and associated components.

The structure and formation of the first sidewall portion 210 have been described above with respect to FIG. 2, and the structure and formation of the bottom case portion 310 have been described above with respect to FIG. 3. In some embodiments, the first sidewall portion 210 and/or the second sidewall portion 250 may comprise internal channels for coolant flow, while the bottom case portion 310 may function as a structural support and a thermal conduction surface. The top case portion 350 may be attached to the first sidewall portion 210, the second sidewall portion 250, and the bottom case portion 310 to complete the housing 400.

As further illustrated in FIG. 4, one or more printed circuit boards may be mounted within the housing 400. In the illustrated embodiment, a first printed circuit board 102 is mounted on the first sidewall portion 210, and a second printed circuit board 105 is mounted on the bottom case portion 310. However, this configuration is merely an example and is not intended to be limiting.

Depending on different applications and design requirements, various alternative mounting arrangements may be employed. For example, one or more printed circuit boards may be mounted only on the bottom case portion 310; on the bottom case portion 310 and the first sidewall portion 210; on the bottom case portion 310 and the second sidewall portion 250; or on the bottom case portion 310 and both the first and second sidewall portions 210 and 250. Other combinations and placements of printed circuit boards within the housing 400 are also contemplated and are within the scope of the present disclosure.

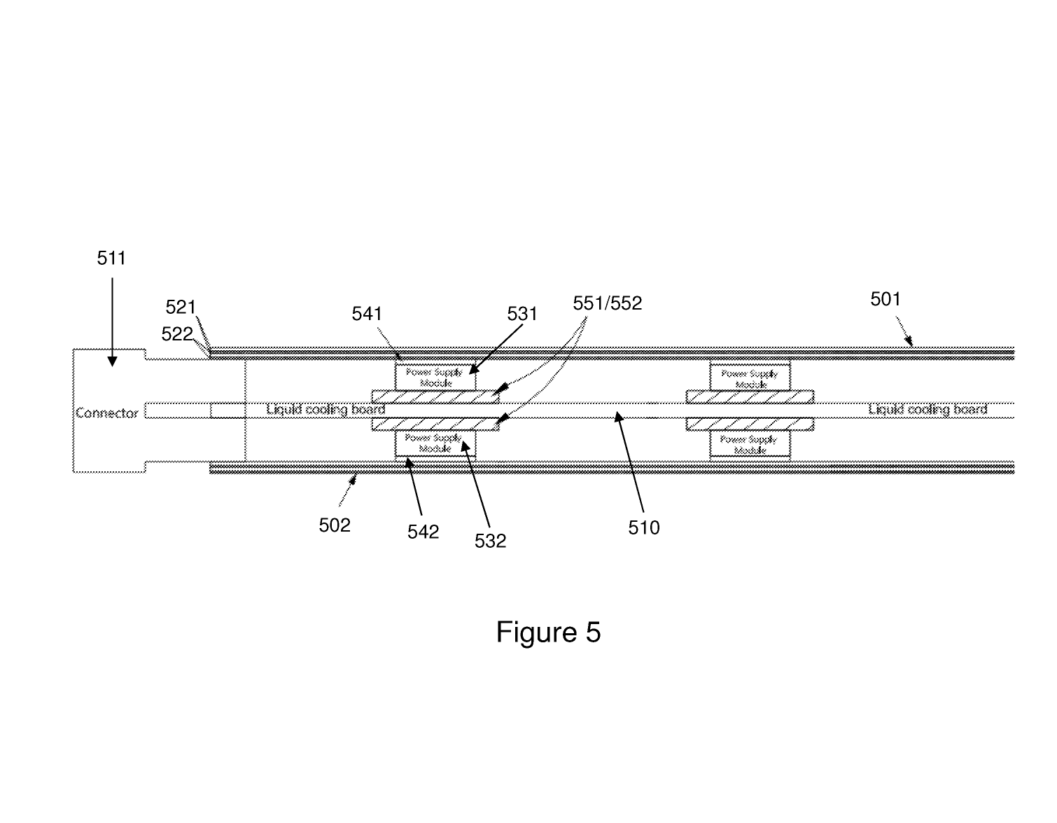

FIG. 5 illustrates a cross-sectional view of a liquid cooling power conversion system in accordance with various embodiments of the present disclosure. The liquid cooling power conversion system comprises a liquid cooling board 510, a first printed circuit board 501, a second printed circuit board 502 and a plurality of power modules 531 and 532. The printed circuit boards (e.g., first printed circuit board 501) comprise a plurality of conductive layers 521 and a plurality of insulation layers 522 as shown in FIG. 5.

As shown in FIG. 5, the liquid cooling board 510 comprises a channel through which coolant flows to cool heat generation components of the system. The first printed circuit board 501 and the second printed circuit board 502 are on opposite sides of the liquid cooling board 510.

A plurality of first power modules 531 is coupled between the liquid cooling board 510 and the first printed circuit board 501. Each first power module 531 is connected to the liquid cooling board 510 through a first soft thermally conductive layer 551, and is connected to the first printed circuit board 501 through surface mount technology (SMT) pins 541. A plurality of second power modules 532 is coupled between the liquid cooling board 510 and the second printed circuit board 502. Each second power module 532 is connected to the liquid cooling board 510 through a second soft thermally conductive layer 552, and is connected to the second printed circuit board 502 through SMT pins 542.

In some embodiments, the plurality of first power modules 531 and the plurality of second power modules 532 are brick dc/dc converters. The system further comprises a connector 511. As shown in FIG. 5, one terminal of the liquid cooling board is inserted into the connector 511.

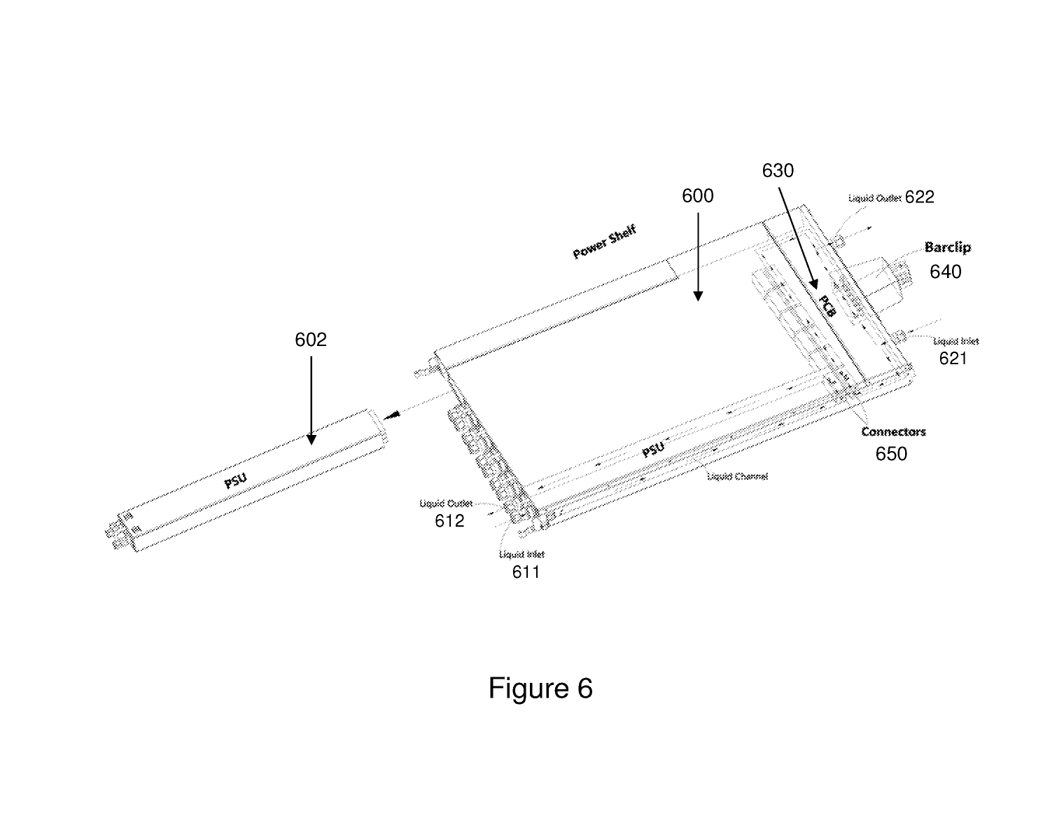

FIG. 6 illustrates a perspective view of a power shelf in accordance with various embodiments of the present disclosure. A plurality of power supply units 602 is on a power shelf 600. Each power supply 602 is connected to the power shelf 600 through a connector 650. A busbar clip (Barclip) 640 is placed at one end of the power shelf 600. The Barclip 640 is a conductive contact structure configured to interface with a busbar. The Barclip 640 can carry a high current (e.g., hundreds of amps). The Barclip 640 has very low contact resistance.

Each power supply unit includes a liquid inlet 611 and a liquid outlet 612. The liquid channel is in the sidewall portion of the housing of the power supply unit as shown in FIG. 2. In operation, as shown in FIG. 6, coolant flows through the liquid channel formed in the first sidewall portion and the second sidewall portion of the power supply unit to cool heat generation components of the power supply unit.

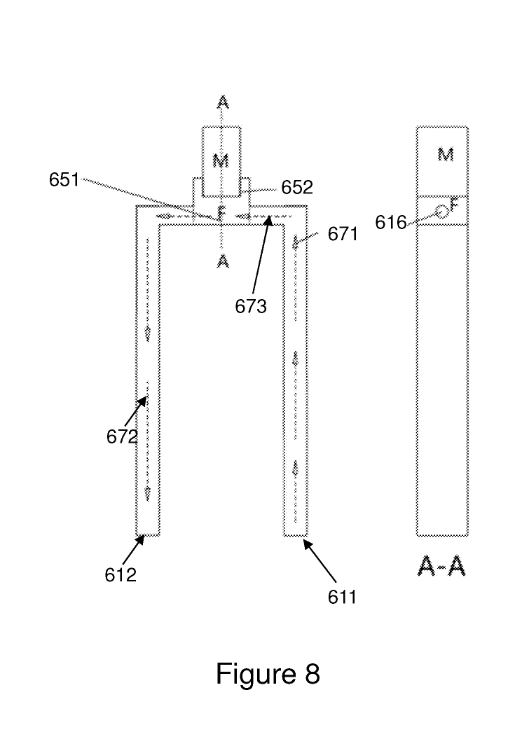

At one end (e.g., rear end) of the power shelf 600, a liquid inlet 621 and a liquid outlet 622 are provided to cool the printed circuit board 630 in the power shelf 600. Furthermore, the cooling channel between the liquid inlet 621 and the liquid outlet 622 is employed to cool the Barclip 640. In some embodiments, the Barclip 640 is in direct thermal contact with the cooling channel, or thermally coupled thereto via a thermally conductive interface material. The detailed operating principles will be discussed below with respect to FIGS. 8-10.

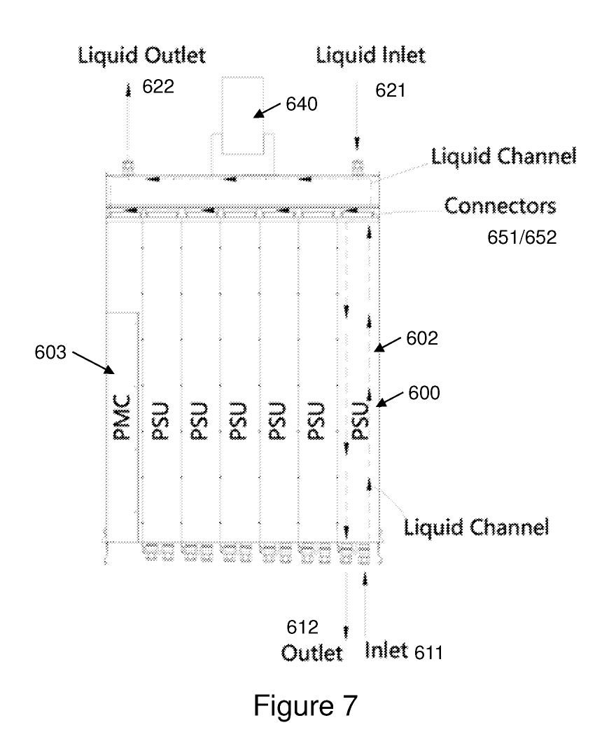

FIG. 7 illustrates a first cooling implementation in a power shelf in accordance with various embodiments of the present disclosure. Each power supply unit includes an inlet and an outlet. A plurality of power supply units 602 and at least one power management controller 603 are placed on the power shelf 600.

For each power supply unit, a liquid channel extends between an inlet 611 and an outlet 612. The liquid channel is configured to provide thermal communication with the heat generation components of the power supply unit.

For each power supply unit, a female connector 651 is attached to the housing of the power supply unit. A corresponding male connector 652 is attached to the power shelf 600. The male connector 652 is configured to be inserted into the female connector 651 and locked together.

The power shelf 600 further comprises a liquid inlet 621 and a liquid outlet 622. The cooling channel between the liquid inlet 621 and the liquid outlet 622 is used to cool the Barclip 640 via the liquid cooling channel formed in the power shelf 600.

FIG. 8 illustrates a first cooling implementation of the male and female connectors in accordance with various embodiments of the present disclosure. The power supply unit comprises a first side wall portion and a second side wall portion. A female connector 651 is attached to the housing of the power supply unit. A corresponding male connector 652 is attached to the power shelf 600. The cross-sectional view taken along lines A-A shows the female connector 651 comprises an opening 616.

The liquid channel includes a first portion 671 in a first sidewall, a second portion 672 in a second sidewall and a connecting channel 673. In some embodiments, the connecting channel 673 is implemented as a pipe connected between the first sidewall and the second sidewall of the power supply unit.

The first portion 671 of the liquid channel comprises a first meandering channel formed in the first sidewall portion and connected to an inlet 611. The second portion 672 of the liquid channel comprises a second meandering channel formed in the second sidewall portion and connected to an outlet 612. The connecting channel 673 is connected between the first meandering channel and the second meandering channel and passes through the female connector 651. The coolant flows through the first meandering channel, the connecting channel and the second meandering channel and into the outlet 612 to absorb heat generated by the heat generation components of the power supply unit. Moreover, the coolant passes through the opening of the female connector 651 to absorb heat generated by the connectors.

In addition, the liquid-cooling concept illustrated in FIG. 8 is not limited to the male and female connectors shown therein. In some embodiments, the same or similar cooling approach may be applied to other high-current conductive interfaces of the power shelf. For example, the power shelf includes a Barclip (not shown, but illustrated in FIG. 7), which is a conductive contact structure configured to interface with a busbar and to carry large currents. Such a Barclip may generate significant heat during operation due to its high current density. In accordance with various embodiments of the present disclosure, the Barclip may be thermally coupled to a liquid cooling channel, such that coolant flowing through the channel absorbs heat generated by the Barclip. Accordingly, the cooling structures and principles described with respect to FIG. 8 may be readily extended to cool a Barclip or other high-current connector structures in the power shelf.

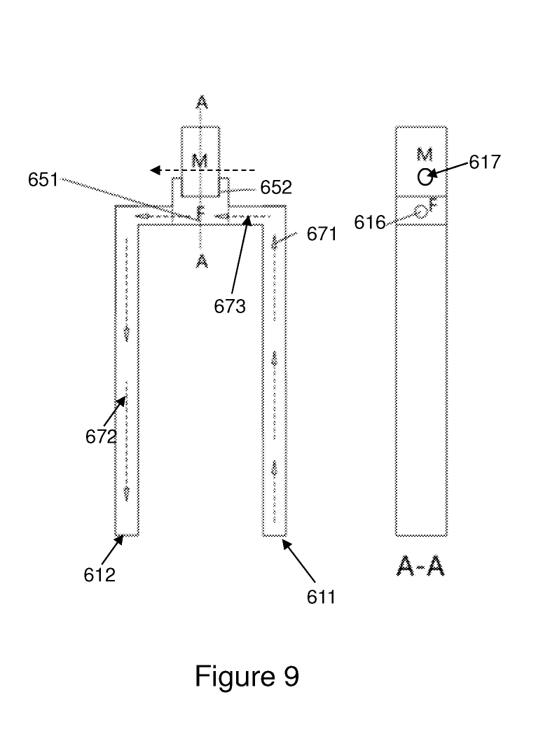

FIG. 9 illustrates a second cooling implementation of the male and female connectors in accordance with various embodiments of the present disclosure. The second cooling implementation of the male and female connectors shown in FIG. 9 is similar to the first cooling implementation of the male and female connectors shown in FIG. 8 except that a power shelf liquid channel 617 passes through the male connector. The power shelf comprises a power shelf liquid inlet and a power shelf liquid outlet. The power shelf liquid channel extends between the power shelf liquid inlet and the power shelf liquid outlet. The power shelf liquid channel is configured to cool heat generation components on the power shelf. As shown in FIG. 9, the power shelf liquid channel passes through the male connector.

In addition, the liquid-cooling concept illustrated in FIG. 9 is not limited to the male and female connectors shown therein. In some embodiments, the same or similar cooling approach may be applied to other high-current conductive interfaces of the power shelf. For example, the power shelf includes a Barclip (not shown, but illustrated in FIG. 7), which is a conductive contact structure configured to interface with a busbar and to carry large currents. Such a Barclip may generate significant heat during operation due to its high current density. In accordance with various embodiments of the present disclosure, the Barclip may be thermally coupled to a liquid cooling channel, such that coolant flowing through the channel absorbs heat generated by the Barclip. Accordingly, the cooling structures and principles described with respect to FIG. 9 may be readily extended to cool a Barclip or other high-current connector structures in the power shelf.

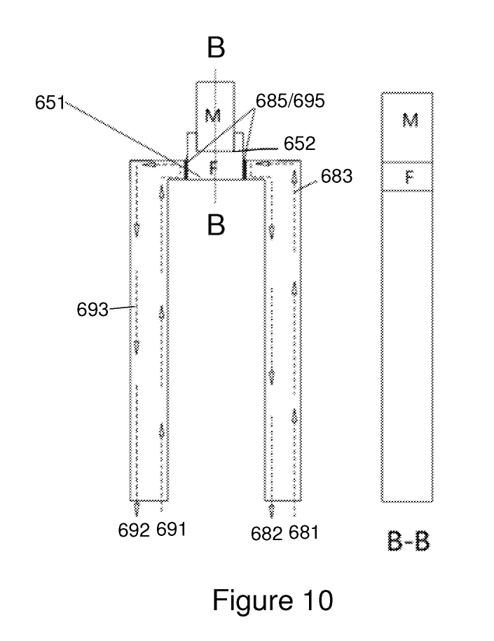

FIG. 10 illustrates a third cooling implementation of the male and female connectors in accordance with various embodiments of the present disclosure. The housing of the power supply unit comprises a first sidewall portion and a second sidewall portion. The first sidewall portion comprises a first inlet 681 and a first outlet 682. A first liquid channel 683 extends between the first inlet 681 and the first outlet 682. The second sidewall portion comprises a second inlet 691 and a second outlet 692. A second liquid channel 693 extends between the second inlet 691 and the second outlet 692. A female connector 651 is attached to the housing of the power supply unit. A male connector 652 is attached to the power shelf. The male connector 652 is configured to be inserted into the female connector 651 and locked together. Neither the first liquid channel 683 nor the second liquid channel 693 passes through the female connector 651. As shown in FIG. 10, the first liquid channel 683 provides contact cooling to a first sidewall of the female connector 651. The second liquid channel 693 provides contact cooling to a second sidewall of the female connector 651. As shown in FIG. 10, a first thermal interface material layer 685 is placed between the first liquid channel 683 and the first sidewall of the female connector 651. A second thermal interface material layer 695 is placed between the second liquid channel 693 and the second sidewall of the female connector 651.

In addition, the liquid-cooling concept illustrated in FIG. 10 is not limited to the male and female connectors shown therein. In some embodiments, the same or similar cooling approach may be applied to other high-current conductive interfaces of the power shelf. For example, the power shelf includes a Barclip (not shown, but illustrated in FIG. 7), which is a conductive contact structure configured to interface with a busbar and to carry large currents. Such a Barclip may generate significant heat during operation due to its high current density. In accordance with various embodiments of the present disclosure, the Barclip may be thermally coupled to a liquid cooling channel, such that coolant flowing through the channel absorbs heat generated by the Barclip. Accordingly, the cooling structures and principles described with respect to FIG. 10 may be readily extended to cool a Barclip or other high-current connector structures in the power shelf.

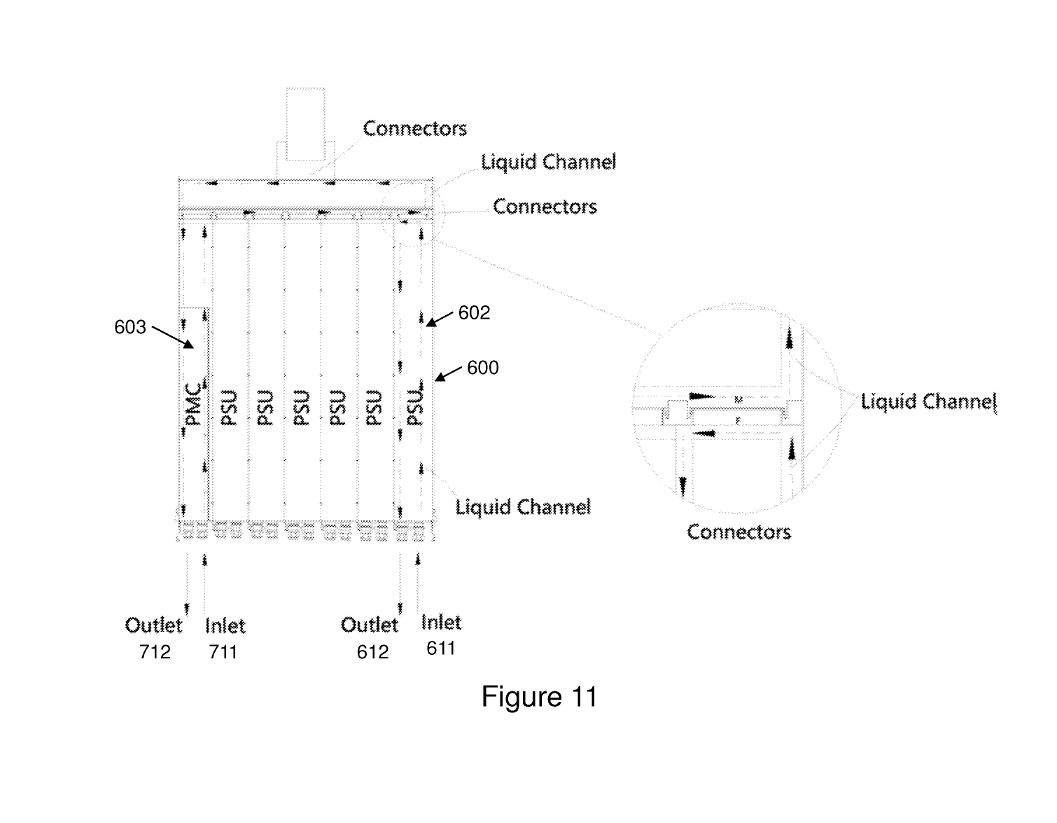

FIG. 11 illustrates a second cooling implementation in the power shelf in accordance with various embodiments of the present disclosure. A plurality of power supply units 602 is on the power shelf 600. A power management controller 603 is on the power shelf 600. The power management controller 603 is in a power management housing. An inlet 711 and an outlet 712 are connected to the power management housing. The coolant flows through the inlet 711, a first sidewall portion of the power management housing, a liquid channel in the power shelf 600 and a second sidewall portion of the power management housing and into the outlet 712 to absorb heat generated by heat generation components in the power shelf 600.

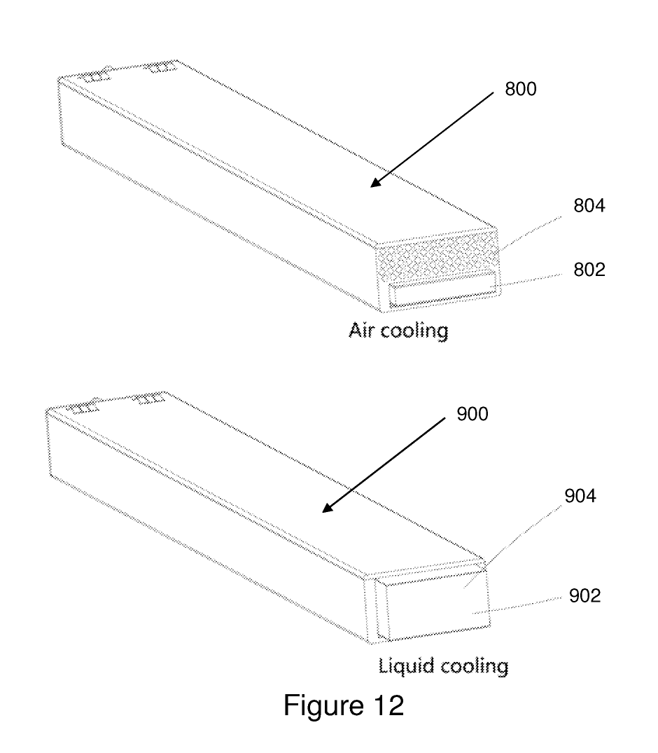

FIG. 12 illustrates a cross-sectional view of another liquid cooling power conversion system in accordance with various embodiments of the present disclosure. An air-cooling power supply 800 comprises a plurality of cooling holes 804. As a result, the connector 802 only occupies a portion of the rear portion of the power supply unit 800.

The liquid cooling power conversion system comprises at least one power supply unit 900. A housing is configured to accommodate this power supply unit. The housing comprises a first sidewall portion, a second sidewall portion, a bottom case portion, a top case portion, a front portion and a rear portion. At least one of the first sidewall portion and the second sidewall portion comprises a channel through which coolant flows to cool heat generation components of the power supply unit. As shown in the bottom portion of FIG. 12, a connector 902 is connected to the power supply unit 900. Since the power supply unit is cooled by the coolant, the traditional air-cooling holes (e.g., cooling holes 804) can be eliminated. As a result of removing the traditional air-cooling holes from the rear end of the housing, the connector is able to occupy at least 90% of a surface area of at least one of the front portion and the rear portion.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps .

What is claimed is:

1. A system comprising:
a plurality of power supply units on a power shelf and connected between a power source and an output voltage bus; and
a plurality of housings, wherein at least one of the plurality of housings is configured to accommodate a power supply unit, and wherein the at least one of the plurality of housings comprises a first sidewall portion, a second sidewall portion, a bottom case portion and a top case portion, and wherein at least one of the first sidewall portion and the second sidewall portion comprises a channel through which coolant flows to cool heat generation components of the power supply unit.

2. The system of claim 1, wherein:
the first sidewall portion comprises the channel through which coolant flows to cool heat generation components of the power supply unit; and
the heat generation components of the power supply unit are mounted on a printed circuit board comprising a plurality of conductive layers and a plurality of insulation layers, and wherein:
the plurality of conductive layers and the plurality of insulation layers are arranged in an alternating manner;
the heat generation components of the power supply unit are mounted on a top conductive layer of the plurality of conductive layers; and
a bottom insulation layer of the plurality of insulation layers is in direct contact with the first sidewall portion.

3. The system of claim 2, wherein:
the bottom insulation layer of the plurality of insulation layers is a thermally conductive but electrically insulating layer to prevent short circuits.

4. The system of claim 2, further comprising:
a plurality of connecting studs mounted on the first sidewall portion; and
a plurality of screw holes formed in the printed circuit board, wherein
each of the plurality of connecting studs extends through a corresponding screw hole, and
the printed circuit board is fastened to the first sidewall portion through a plurality of screws.

5. The system of claim 4, wherein:
the first sidewall portion is configured as a system ground; and
at least one of the plurality of connecting studs is configured as a connecting channel between the printed circuit board and the system ground.

6. The system of claim 1, further comprising:
an inlet and an outlet, wherein the channel extends between the inlet and the outlet, and wherein the channel is configured to provide thermal communication with the heat generation components.

7. The system of claim 6, further comprising:
a female connector attached to the at least one of the plurality of housings; and
a male connector attached to the power shelf, wherein the male connector is configured to be inserted into the female connector and locked together.

8. The system of claim 7, further comprising:
a connecting channel, wherein:
the first sidewall portion comprises a first meandering channel connected to the inlet; and
the second sidewall portion comprises a second meandering channel connected to the outlet, and wherein the connecting channel is connected between the first meandering channel and the second meandering channel, and passes through the female connector, and the coolant flows through the first meandering channel, the connecting channel and the second meandering channel and into the outlet to absorb heat generated by the heat generation components.

9. The system of claim 7, further comprising:
a power shelf liquid inlet and a power shelf liquid outlet, wherein a power shelf liquid channel extends between the power shelf liquid inlet and the power shelf liquid outlet, and wherein the power shelf liquid channel is configured to cool heat generation components on the power shelf, and wherein the power shelf liquid channel passes through the male connector.

10. The system of claim 1, wherein:
the first sidewall portion comprises a first inlet and a first outlet;
a first channel extends between the first inlet and the first outlet;
the second sidewall portion comprises a second inlet and a second outlet;
a second channel extends between the second inlet and the second outlet; and
a female connector attached to the housing and a male connector attached to the power shelf, wherein the male connector is configured to be inserted into the female connector and locked together, and wherein:
the first channel contacts the female connector through a first thermally conductive structure to dissipate heat; and
the second channel contacts the female connector through a second thermally conductive structure to dissipate heat.

11. The system of claim 1, further comprising:
a power management controller in a power management housing; and
an inlet and an outlet connected to the power management housing, wherein the coolant flows through the inlet, a first sidewall portion of the power management housing, a liquid channel in the power shelf and a second sidewall portion of the power management housing and into the outlet to absorb heat generated by heat generation components in the power shelf.

12. A system comprising:
a liquid cooling board comprising a channel through which coolant flows to cool heat generation components of the system;
a first printed circuit board and a second printed circuit board on opposite sides of the liquid cooling board;
a plurality of first power modules coupled between the liquid cooling board and the first printed circuit board, wherein each first power module is connected to the liquid cooling board through a first soft thermally conductive layer; and
a plurality of second power modules coupled between the liquid cooling board and the second printed circuit board, wherein each second power module is connected to the liquid cooling board through a second soft thermally conductive layer.

13. The system of claim 12, wherein:
the plurality of first power modules and the plurality of second power modules are brick dc/dc converters.

14. The system of claim 12, further comprising:
a connector, wherein one terminal of the liquid cooling board is inserted into the connector.

15. The system of claim 12, wherein:
the plurality of first power modules is coupled to the first printed circuit board through a plurality of first SMT pins; and
the plurality of second power modules is coupled to the second printed circuit board through a plurality of second SMT pins.

16. A system comprising:
a power shelf configured to receive a plurality of power supply units and to provide an output voltage bus;
a busbar clip configured to electrically couple at least one of the plurality of power supply units to the output voltage bus, wherein the busbar clip is configured to carry a high current; and
a liquid cooling channel disposed in the power shelf, wherein the busbar clip is thermally coupled to the liquid cooling channel such that coolant flowing through the liquid cooling channel absorbs heat generated by the busbar clip during operation.

17. The system of claim 16, wherein:
the liquid cooling channel is formed in a structural portion of the power shelf adjacent to the busbar clip.

18. The system of claim 16, wherein:
the busbar clip is in direct thermal contact with the liquid cooling channel.

19. The system of claim 16, further comprising:
a thermally conductive interface material disposed between the busbar clip and the liquid cooling channel to enhance heat transfer.

20. The system of claim 16, wherein:
the busbar clip is configured as a conductive contact structure that interfaces with a busbar and carries a high current during operation.
